(19) United States
(12) Patent Application Publication
(10) Pub. No.: US 2014/0217410 A1
(43) Pub. Date: Aug. 7, 2014

(54) Array Substrate, Display Device and Manufacturing Method Thereof

(71) Applicant: Shenzhen China Star Optoelectronics Technology Co., Ltd., Shenzhen, Guangdong (CN)

(72) Inventor: Tsung-Yi Hsu, Shenzhen City (CN)

(73) Assignee: Shenzhen China Star Optoelectronics Technology Co., Ltd., Shenzhen, Guangdong (CN)

(21) Appl. No.: 13/818,988

(22) PCT Filed: Feb. 19, 2013
(86) PCT No.: PCT/CN2013/071662

§ 371 Date: Feb. 25, 2013

(30) Foreign Application Priority Data
Feb. 5, 2013 (CN) 201310046310.2

(51) Int. Cl. H01L 23/02; H01L 27/06; H01L 49/02; H01L 21/84

(52) U.S. Cl. CPC H01L 23/02; H01L 21/845; H01L 27/0629; H01L 28/40
USPC 257/59; 438/155; 257/71

(57) ABSTRACT

The present invention provides a manufacturing method of array substrate, which comprises: substrate; source, drain, driving electrode, and first capacitance electrode being formed on substrate; a first dielectric layer being formed to cover source, drain, driving electrode, and first capacitance electrode; first dielectric layer comprising first section covering first capacitance and second section covering the driving electrode; second section being thicker than first section; second capacitance electrode being formed on the first section of the first dielectric layer; first capacitor being formed with second capacitance electrode, first capacitance electrode, and first dielectric layer in between. Through this invention, the glue sealing of display device with present invention of array substrate is more effective.

### BACKGROUND OF THE INVENTION

1. Field of the Invention

The present invention relates to the field of liquid crystal displaying techniques, and in particular to an array substrate, display device, and manufacturing method thereof.

2. The Related Arts

The liquid crystal display panel of known technique usually comprises a color film substrate and array substrate. The manufacturing process of the liquid crystal display panel usually comprises array process, cell process, and module process. The array process mainly comprises the manufacturing process of array substrate. The cell process mainly comprises attaching array substrate and color film substrate together. The module process comprises FPC (Flexible Printed Circuit) and other circuit assembling.

TFT (Thin-Film Transistor), capacitor, and pixel electrode are formed on the array substrate in array configuration. A driving electrode is formed in the surrounding area. The driving electrode controls the power of TFT on or off; therefore, the driving electrode connects TFT and FPC. In the cell process, before attaching array substrate and color film substrate together, the frames of array substrate and color film substrate are glue sealed; wherein, glue sealing comprises gluing and setting.

OLED (Organic Electroluminesence Display) panel is a new development trend for the liquid crystal display panel in the future; however, OLED is very sensitive to moisture and oxidant; therefore, the conditions for the sealing are more severe.

In known technique, the sealing process of OLEO is to heat the frame seal to set by applying laser beam after the gluing. The temperature for laser beam to set the frame seal is over one thousand degrees celsius. However, the section covered with the frame seal is identical to the position of driving electrode. If the frame seal and driving electrode have direct contact during the process of setting, the peeling of the frame seal from the position of driving electrode can happen.

### SUMMARY OF THE INVENTION

The technical issue to be addressed by the present invention is to provide an array substrate, display device, and manufacturing method thereof; as a result, to improve the frame sealing.

The present invention provides a manufacturing method of array substrate, which comprises: a substrate; source, drain, driving electrode, and first capacitance electrode being formed on the substrate; a first dielectric layer being formed to cover source, drain, driving electrode, and first capacitance electrode; the first dielectric layer comprising a first section covering first capacitance and a second section covering the driving electrode; the second section being thicker than the first section; glass hot melt glue being formed on the second section; a second capacitance electrode being formed on the first section of the first dielectric layer; first capacitor being formed with second capacitance electrode, first capacitance electrode, and the first dielectric layer in between.

According to a preferred embodiment of the present invention, the thickness of the first section is two hundred to one thousand Å; the thickness of the second section being one thousand to eight thousand Å.

According to a preferred embodiment of the present invention, the steps after forming the first dielectric layer comprise: a pixel electrode being formed on the first dielectric layer to connect source; a organic material layer being formed on the first dielectric layer to cover the second electrode plate; the pixel electrode being exposed on the organic material layer; several extrude spacers being formed on the organic material layer.

According to a preferred embodiment of the present invention, the step of forming source, drain, driving electrode, and first capacitance electrode on the substrate comprises: a second dielectric layer being formed on the substrate; a semi-conductor layer and third capacitance electrode being formed on the second dielectric layer; a third dielectric layer being formed on the second dielectric layer to cover semi-conductor layer and third capacitance electrode; a gate and fourth capacitance electrode being formed on the third dielectric layer; the gate being opposite the semi-conductor layer; a second capacitor being formed with fourth capacitance electrode, third capacitance electrode, and the third dielectric layer in between; a fourth dielectric layer being formed on the third dielectric layer to cover the gate and fourth capacitance electrode; the source, drain, driving electrode, and first capacitance being formed on the fourth dielectric layer; the source and drain being connected to the semi-conductor layer.

The present invention provides an array substrate, which comprises: a substrate, driving electrode, first capacitor, source, drain, and first capacitance electrode; the first capacitor comprising first capacitance electrode and second capacitance electrode; source, drain, driving electrode, and first capacitance electrode being formed on the substrate; the first dielectric layer covering source, drain, driving electrode, and first capacitance electrode; the first dielectric layer comprising a first section covering the first capacitance electrode and second section covering driving electrode; the second section being thicker than the first section; glass hot melt glue being formed on the second section; a second capacitance electrode being formed on the first section.

According to a preferred embodiment of the present invention, the thickness of the first section is two hundred to one thousand Å; the thickness of the second section being one thousand to eight thousand Å.

According to a preferred embodiment of the present invention, the array substrate comprises: a pixel electrode, organic material layer, and spacer; the pixel electrode being formed on the first dielectric layer to connect source: the organic material layer being formed on the first dielectric layer to cover the second electrode plate; the pixel electrode being exposed on the organic material layer; spacers being extrude and formed on the organic material layer.

According to a preferred embodiment of the present invention, the second capacitance electrode is made of metal material or transparent conductive material.

According to a preferred embodiment of the present invention, the array substrate comprises: the second dielectric layer, semi-conductor layer, third dielectric layer, gate, fourth dielectric layer, and second capacitor; the second capacitor comprising the third capacitance electrode and fourth capacitance electrode; the second dielectric layer being formed on the base plat; the semi-conductor layer and third capacitance electrode being in between second dielectric layer and third dielectric layer; the gate and fourth capacitance electrode being in between the third dielectric layer and fourth dielectric layer; the source and gate being connected to the semi-conductor layer.

The present invention provides a display device, which comprises: an array substrate, color film substrate, and mold frame surrounding with glass hot melt glue; the mold frame being in between the array substrate and the color film substrate; the array substrate comprising a substrate, driving electrode, first capacitor, source, drain, and first dielectric layer; the first capacitor comprising first capacitance electrode and second capacitance electrode; source, drain, driving electrode, and first capacitance electrode being formed on the substrate; the first dielectric layer covering source, drain, driving electrode, and first capacitance electrode; the first dielectric layer comprising a first section covering the first capacitance electrode and second section covering driving electrode; the second section being thicker than the first section; glass hot melt glue being formed on the second section; a second capacitance electrode being formed on the first section.

According to a preferred embodiment of the present invention, the thickness of the first section is two hundred to one thousand Å; the thickness of the second section being one thousand to eight thousand Å.

According to a preferred embodiment of the present invention, the array substrate comprises: a pixel electrode, organic material layer, and spacer; the pixel electrode being formed on the first dielectric layer to connect source; the organic material layer being formed on the first dielectric layer to cover the second electrode plate; the pixel electrode being exposed on the organic material layer; spacers being extrude and formed on the organic material layer.

According to a preferred embodiment of the present invention, the second capacitance electrode is made of metal material or transparent conductive material.

According to a preferred embodiment of the present invention, the array substrate comprises: the second dielectric layer, semi-conductor layer, third dielectric layer, gate, fourth dielectric layer, and second capacitor; the second capacitor comprising the third capacitance electrode and fourth capacitance electrode; the second dielectric layer being formed on the base plat; the semi-conductor layer and third capacitance electrode being in between second dielectric layer and third dielectric layer; the gate and fourth capacitance electrode being in between the third dielectric layer and fourth dielectric layer: the source and gate being connected to the semi-conductor layer.

The efficacy of the present invention is that to be distinguished from the state of the art. The present invention of the first dielectric layer of array substrate comprises: the first section in between first capacitance electrode, and second capacitance electrode and the second section covering the driving electrode; wherein, the second section being thicker than the first section. Through this design, not only the basic charge storage capacity of the first capacitor can be remained, but also the peeling of glass hot melt glue caused by directly contacting to the driving electrode during the frame sealing process can be avoid. In addition, the second section corresponding to the driving electrode is thicker; as a result, the frame sealing is more effective in the process.

### BRIEF DESCRIPTION OF THE DRAWINGS

FIG. 1 is a front view showing the structure of an array substrate according to the present invention;

FIG. 2 is an overhead view showing the array substrate applied in the display device;

FIG. 3 is a front view showing the structure of area A of the display device in FIG. 2;

FIG. 4 is a flow diagram showing the manufacturing method of the array substrate.

### DETAILED DESCRIPTION OF THE PREFERRED EMBODIMENTS

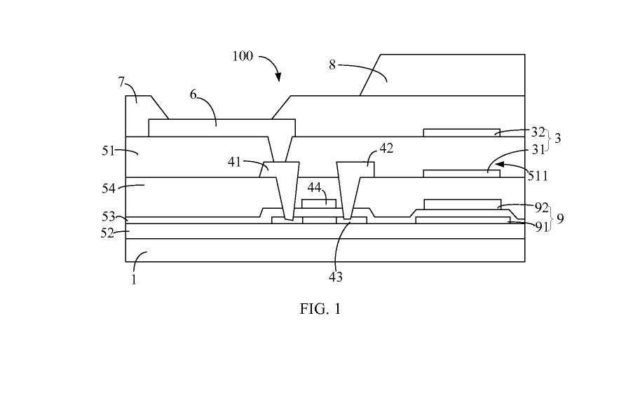

Referring to FIGS. 1 and FIGS. 2, the present invention of the array substrate comprises: substrate 1, driving electrode 2, first capacitor 3, TFT layer (not on the figures), first dielectric layer 51, pixel electrode 6, organic material layer 7, and spacer 8. First capacitor 3 comprises first capacitance electrode 31 and second capacitance electrode 32.

TFT layer comprises: second dielectric layer 52, semi-conductor layer 43, third dielectric layer 53, gate 44, fourth dielectric layer 54, source 41, drain 42, and second capacitor 9. Second capacitor 9 comprises: third capacitance electrode 91 and fourth capacitance electrode 92.

Second dielectric layer 52 is formed on substrate 1. Semi-conductor layer 43 and third capacitance electrode 91 is formed on a side of second dielectric layer 52 away from substrate 1. Third capacitance electrode 91 and semi-conductor layer 43 can be formed in different processes or in the same process. If third capacitance electrode 91 and semi-conductor layer 43 are formed in the same process, the material used to form third capacitance electrode 91 and semi-conductor layer 43 is the same, wherein; third capacitance electrode 91 is also made of semi-conductor material.

Third dielectric layer 53 is formed on second dielectric layer 52. Third dielectric layer 53 covers semi-conductor layer 43 and third capacitance electrode 91 to position third capacitance electrode 91 and semi-conductor layer 43 in between second dielectric layer 52 and third dielectric layer 53.

Gate 44 and fourth capacitance electrode 92 are formed on third dielectric layer 53. Gate 44 and fourth capacitance electrode 92 are formed in the same process and different processes. Fourth dielectric layer is formed on third dielectric layer 53. Fourth dielectric layer 54 covers gate 44 and fourth capacitance electrode 92 to position gate 44 and fourth capacitance electrode 92 in between third dielectric layer 53 and fourth dielectric layer 54.

Source 41, drain 42, first capacitance electrode 31, and driving electrode 2 are formed on fourth dielectric layer 54 in the same process and different processes. Driving electrode 2 is formed on a location close to a side of array substrate 100. First dielectric layer 51 is formed on fourth dielectric layer 54. First dielectric layer 51 covers source 41, drain 42, first capacitance electrode 31, and driving electrode 2. First dielectric layer 51 comprises first section 511 covering first capacitance electrode 31 and second section 512 covering driving electrode 2. Second section 512 is thicker than first section 511. According to a preferred embodiment of the present invention, the thickness of first section 511 is two hundred to one thousand Å. The thickness of second section 512 is one thousand to eight thousand Å.

Second capacitance electrode 32 is formed on first section 511 of first dielectric layer 51. First capacitor 3 is formed with first dielectric layer 51 in between first capacitance electrode 31 and second capacitance electrode 32. Because the thickness of first dielectric layer 51 in between first capacitance electrode 31 and second capacitance electrode 32 is thinner, first capacitor 3 can have higher charge storage capacity to meet the usage needs.

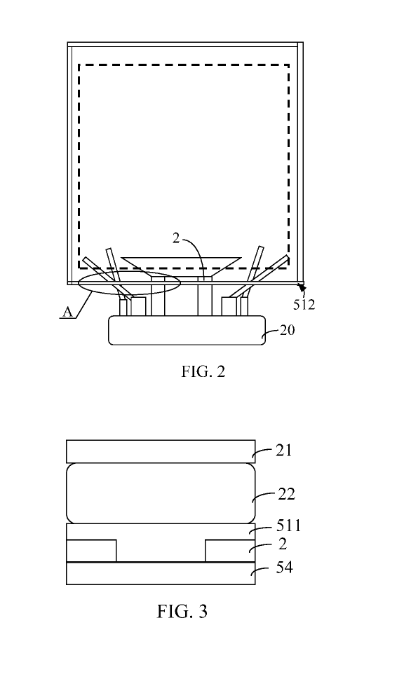

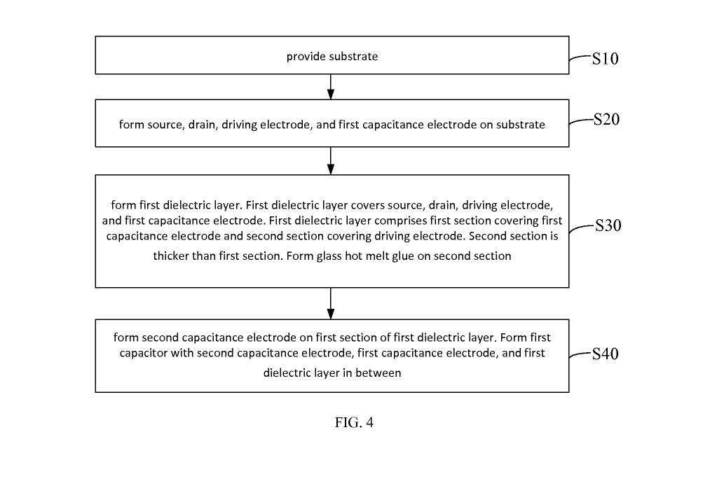

As shown in FIGS. 2 and 3, first section 511 of first dielectric layer 51 covers driving electrode 2. Glass hot melt glue 22 is formed on first section 511 to seal array substrate 100 and color film substrate 21.

The sealing process of glass hot melt glue 22 is: first, to pour glass hot melt glue on glue seal area (not shown in figures), which is the surrounding area of array substrate 100; wherein, the glue seal area and second section 512 are partially overlapping; then, to heat the glass hot melt glue to set by applying laser beam. In the instant embodiment of present invention, because first dielectric layer 51 is thicker and formed in between driving electrode 2 and glass hot melt glue 22, first dielectric layer 51 is a transition between driving electrode 2 and glass hot melt glue 22; as a result, glass hot melt glue 22 can have better setting and sealing performance.

Furthermore, pixel electrode 6 is formed on first dielectric layer 51. Pixel electrode 6 is connected to source 41. Pixel electrode 6 and second capacitance electrode 32 are formed in the same process and different processes. According to a preferred embodiment of the present invention, pixel electrode 6 and second capacitance electrode 32 are formed in the same process. Both pixel electrode 6 and second capacitance electrode 32 are made of transparent conductive material or silver. When pixel electrode 6 and second capacitance electrode 32 are formed in different processes, second capacitance electrode 32 can be made of other conductive materials.

Organic material layer 7 is formed on first dielectric layer 51. Organic material layer 7 covers second electrode plate and makes pixel electrode 6 exposed. Spacer 8 are disposed on organic material layer 7 with an interval and extruded to support color film substrate 21 attached to array substrate 100.

The area organic material layer 7 disposed on is smaller than first dielectric layer 51. Organic material layer 7 is not disposed on the frame glue area of array substrate 100; therefore, glass hot melt glue 22 is poured on first dielectric layer 51 being disposed on the top layer of the frame glue area.

According to the present invention, first dielectric layer 51, second dielectric layer 52. third dielectric layer 53, and fourth dielectric layer 54 are made of silicon oxide or silicon nitride. In the practice, the materials of dielectric layers are not limited to aforementioned materials. In addition, adjacent dielectric layers can be made of the same materials and different materials.

The efficacy of the present invention is that to be distinguished from the state of the art. The present invention of first dielectric layer 51 of array substrate 100 comprises: first section 511 in between first capacitance electrode 31, and second capacitance electrode 32 and second section 512 covering driving electrode 2; wherein, second section 512 being thicker than first section 511. Through this design, not only the basic charge storage capacity of first capacitor 3 can be remained, but also the peeling of glass hot melt glue 22 caused by directly contacting to driving electrode 2 during the frame sealing process can be avoid. In addition, second section 512 corresponding to driving electrode 2 is thicker; as a result, the frame sealing is more effective in the process.

As shown in FIG. 2, the present invention provides a display device, which comprises: array substrate 100, color film substrate 21, FPC 20, and mold frame surrounding glass hot melt glue 22 in the aforementioned embodiments. The mold frame is in between array substrate 100 and color film substrate 21. FPC 20 is connected to driving electrode 2.

As shown in FIG. 2, the present invention provides a manufacturing method of an array substrate, which comprises:

S10: provide substrate 1.

Substrate 1 can be a transparent plate made of glass or other transparent materials.

S20: form source 41, drain 42, driving electrode 2, and first capacitance electrode 31 on substrate 1.

S30: form first dielectric layer 51. First dielectric layer 51 covers source 41, drain 42, driving electrode 2, and first capacitance electrode 31. First dielectric layer 51 comprises first section 511 covering first capacitance electrode 31 and second section 512 covering driving electrode 2. Second section 512 is thicker than first section 511. Form glass hot melt glue 22 on second section 512.

S40: form second capacitance electrode 32 on first section 511 of first dielectric layer 51. Form first capacitor 3 with second capacitance electrode 32, first capacitance electrode 31, and first dielectric layer 51 in between.

To be specific, S20 comprises: form second dielectric layer 52 on substrate 1. Form semi-conductor layer 43 and third capacitance electrode 91 on second dielectric layer 52. Form third dielectric layer 53 on second dielectric layer 52 to cover semi-conductor layer 43 and third capacitance electrode 91. Form gate 44 and fourth capacitance electrode 92 on third dielectric layer 53. Gate 44 is opposite semi-conductor layer 43. Form second capacitor 9 with fourth capacitance electrode 92, third capacitance electrode 91, and third dielectric layer in between. Form fourth dielectric layer 54 on third dielectric layer 53 to cover gate 44 and fourth capacitance electrode 92. Form source 41, drain 42, first capacitance electrode 31, and driving electrode 2 on fourth dielectric layer 92. Connect source 41 and drain 42 to semi-conductor layer 43.

In S30, according to a preferred embodiment of the present invention, the thickness of first section 511 is two hundred to one thousand A. The thickness of second section 512 is one thousand to eight thousand A.

Furthermore, in S30, form pixel electrode 6 on first dielectric layer 51. Connect pixel electrode 6 to source 41. Form pixel electrode 6 in S40 or before/after S40. When pixel electrode 6 and second capacitance electrode 32 are formed in the same process, both pixel electrode 6 and second capacitance electrode 32 are made of the same material, which is transparent conductive material or silver.

After forming pixel electrode 6, form organic material layer 7 on first dielectric layer 51 to cover second capacitance electrode 32. Pixel electrode 6 is exposed on organic material layer 7. Finally, form several extrude spacer 8 on organic material layer 7 to support color film substrate 21 attached to array substrate 100 of display device.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the clams of the present invention.

What is claimed:

1. A manufacturing method of array substrate, which comprises:
a substrate;
source, drain, driving electrode, and first capacitance electrode being formed on the substrate;
a first dielectric layer being formed to cover source, drain, driving electrode, and first capacitance electrode;
the first dielectric layer comprising a first section covering first capacitance and a second section covering the driving electrode;
the second section being thicker than the first section;
glass hot melt glue being formed on the second section;
a second capacitance electrode being formed on the first section of the first dielectric layer; and, first capacitor being formed with second capacitance electrode, first capacitance electrode, and the first dielectric layer in between.

2. The manufacturing method of array substrate as claimed in claim 1, characterized in that:
the thickness of the first section is two hundred to one thousand Å; and
the thickness of the second section being one thousand to eight thousand Å.

3. The manufacturing method of array substrate as claimed in claim 1, characterized in that:
the steps after forming the first dielectric layer comprise:
a pixel electrode being formed on the first dielectric layer to connect source;
a organic material layer being formed on the first dielectric layer to cover the second electrode plate;
the pixel electrode being exposed on the organic material layer; and,
several extrude spacers being formed on the organic material layer.

4. The manufacturing method of array substrate claimed in claim 1, characterized in that:
the step of forming source, drain, driving electrode, and first capacitance electrode on the substrate comprises:
a second dielectric layer being formed on the substrate;
a semi-conductor layer and third capacitance electrode being formed on the second dielectric layer;
a third dielectric layer being formed on the second dielectric layer to cover semi-conductor layer and third capacitance electrode;
a gate and fourth capacitance electrode being formed on the third dielectric layer; the gate being opposite the semi-conductor layer;
a second capacitor being formed with fourth capacitance electrode, third capacitance electrode, and the third dielectric layer in between;
a fourth dielectric layer being formed on the third dielectric layer to cover the gate and fourth capacitance electrode;
the source, drain, driving electrode, and first capacitance being formed on the fourth dielectric layer; and,
the source and drain being connected to the semi-conductor layer.

5. An array substrate which comprises:
a substrate, driving electrode, first capacitor, source, drain, and first capacitance electrode;
the first capacitor comprising first capacitance electrode and second capacitance electrode;
source, drain, driving electrode, and first capacitance electrode being formed on the substrate;
the first dielectric layer covering source, drain, driving electrode, and first capacitance electrode;
the first dielectric layer comprising a first section covering the first capacitance electrode and second section covering driving electrode;
the second section being thicker than the first section;
glass hot melt glue being formed on the second section; and,
a second capacitance electrode being formed on the first section.

6. The array substrate as claimed in claim 5, characterized in that:
the thickness of the first section is two hundred to one thousand Å; and,
the thickness of the second section being one thousand to eight thousand Å.

7. The array substrate as claimed in claim 5, characterized in that:
the array substrate comprises:
a pixel electrode, organic material layer, and spacer;
the pixel electrode being formed on the first dielectric layer to connect source;
the organic material layer being formed on the first dielectric layer to cover the second electrode plate;
the pixel electrode being exposed on the organic material layer; and,
spacers being extrude and formed on the organic material layer.

8. The array substrate as claimed in claim 5, characterized in that:
the second capacitance electrode is made of metal material or transparent conductive material.

9. The array substrate as claimed in claim 8, characterized in that:
the array substrate comprises:
the second dielectric layer, semi-conductor layer, third dielectric layer, gate, fourth dielectric layer, and second capacitor;
the second capacitor comprising the third capacitance electrode and fourth capacitance electrode;
the second dielectric layer being formed on the base plat; the semi-conductor layer and third capacitance electrode being in between second dielectric layer and third dielectric layer;
the gate and fourth capacitance electrode being in between the third dielectric layer and fourth dielectric layer; and,
the source and gate being connected to the semi-conductor layer.

10. A display device, which comprises:
an array substrate, color film substrate, and mold frame surrounding with glass hot melt glue;
the mold frame being in between the array substrate and the color film substrate;
the array substrate comprising a substrate, driving electrode,, first capacitor, source, drain, and first dielectric layer;
the first capacitor comprising first capacitance electrode and second capacitance electrode;
source, drain, driving electrode, and first capacitance electrode being formed on the substrate;
the first dielectric layer covering source, drain, driving electrode, and first capacitance electrode;
the first dielectric layer comprising a first section covering the first capacitance electrode and second section covering driving electrode;
the second section being thicker than the first section;
glass hot melt glue being formed on the second section; and,
a second capacitance electrode being formed on the first section.

11. The display device as claimed in claim 10, characterized in that:
the thickness of the first section is two hundred to one thousand Å; and,
the thickness of the second section being one thousand to eight thousand Å.

12. The display device as claimed in claim 10, characterized in that:
the array substrate comprises:
a pixel electrode, organic material layer, and spacer;
the pixel electrode being formed on the first dielectric layer to connect source;
the organic material layer being formed on the first dielectric layer to cover the second electrode plate;
the pixel electrode being exposed on the organic material layer; and,
spacers being extrude and formed on the organic material layer.

13. The display device as claimed in claim 10, characterized in that:
the second capacitance electrode is made of metal material or transparent conductive material.

14. The display device as claimed in claim 13, characterized in that:
the array substrate comprises:
the second dielectric layer, semi-conductor layer, third dielectric layer, gate, fourth dielectric layer, and second capacitor;
the second capacitor comprising the third capacitance electrode and fourth capacitance electrode;
the second dielectric layer being formed on the base plat; the semi-conductor layer and third capacitance electrode being in between second dielectric layer and third dielectric layer;
the gate and fourth capacitance electrode being in between the third dielectric layer and fourth dielectric layer; and, the source and gate being connected to the semi-conductor layer.
